(19) United States
(12) Patent Application Publication
(10) Pub. No.: US 2025/0290964 A1
(43) Pub. Date: Sep. 18, 2025

(54) METHOD FOR MONITORING PLUG-IN UNITS IN A RACK

(71) Applicant: Robert Bosch GmbH, Stuttgart (DE)

(72) Inventors: Abhiram Ragudas, Stuttgart-Degerloch (DE); Panagiotis Kosioris, Urbach (DE)

(21) Appl. No.: 19/069,860

(22) Filed: Mar. 4, 2025

(30) Foreign Application Priority Data
Mar. 14, 2024 (DE) 10 2024 202 387.6

(51) Int. Cl. G01R 31/00; B60R 16/023

(52) U.S. Cl. CPC G01R 31/007; B60R 16/0231

(57) ABSTRACT

A method for monitoring plug-in units in a rack. A number of plug-in units and a power supply plug-in unit are provided in the rack. A microcontroller, a power supply module, and a monitoring assembly are arranged in each of the plug-in units. At least one of the plug-in units is effected by communication between a monitoring unit in the power supply plug-in unit and the monitoring assembly in the monitored plug-in unit.

### FIELD

The present invention relates to a method for monitoring plug-in units in a rack, in particular in a motor vehicle, and to a monitoring assembly for carrying out the method.

### BACKGROUND INFORMATION

The currently used automotive E/E architectures (E/E: electronic/electrical) have reached their limits in terms of scalability. An E/E zone architecture is a concept that reflects the technological change that addresses the growing complexity and computational requirements of the automotive E/E system, in order to meet the expectations of the new generation of automotive consumers and implement new industry trends.

The transition from current flat automotive E/E architectures to consolidated zone architectures comprises a few intermediate steps, such as a central gateway, a domain controller and distributed zone architectures.

All these intermediate steps introduce new device classes, communication topologies and implementations, such as high-performance modular multi-purpose computers of various types, high-speed trunk lines and modular software as a service (Saas). This is aimed at:
a reduction in hardware,
a reduction in wiring and
increased functionality.

If the physical dimensions of the vehicle in a zone architecture are taken into account, there are three device classes:

Edge devices, such as sensors and actuators, along with conventional control units corresponding to those of other architectures.

The zone gateway acts as a local connectivity hub, integrating a plurality of low-speed interfaces, mostly in a conventional manner, and forwarding data via a single high-speed connection, such as Ethernet, to the trunk line. The zone gateway can also carry out edge processing and offload data or prepare them for a vehicle server for processing, so that workload and bandwidth are reduced.

The task of the vehicle server is to reduce the number of physical control units (ECU: electronic control unit) in the vehicle, for example by merging or consolidating hardware components. The vehicle server is not necessarily a single physical device; rather, it can be implemented as a modular server by connecting a plurality of high-performance control units, grouping systems on chip (SoC) on the same printed circuit board (PCB) or by using a basic trunk line with expansion cards (rack architectures).

With regard to operational safety and data security, objectives such as secure start-up, resource isolation, network protection and secure storage should be taken into account, in particular for hardware integration topologies in which a basic trunk line with expansion cards is selected. Since some logical and technical resources are shared across a plurality of physical instances, hosting security functions and security-critical functions, i.e. functions with a high ASIL rating, are thus used.

A device for switching a control unit on and off in a motor vehicle is described in European Patent No. EP 1 128 536 B1, wherein the control unit is arranged in a dual-voltage vehicle electrical system. A logic unit is provided in this device, which logic unit has an input for a supply voltage monitoring signal.

With the rack approach, there is an option for consolidating the plurality of control units into one physical housing. The control units are distributed throughout the vehicle.

The key concept within the rack is to divide fixed ratios of computing, storage, and networking into separate pools, which can be interconnected as needed or combined into logical systems, boards, enclosures, or nodes optimized for specific applications.

Currently, whenever a control unit has an ASIL functionality requirement, the provider must add ASIL-D capable components for diagnostics and isolation paths. This is also the case with racks and their enclosures or plug-in units, which contradicts the idea of having a central high-performance ASIL-D-capable node that takes over all or part of the ASIL-D functionality, which greatly reduces the number of microcontrollers on board and simplifies hardware design in terms of materials and development costs.

One such function is the rack power supply with a high level of integration and high requirements in terms of fault tolerance and availability.

### SUMMARY

The present invention provides, among other things, a method and an assembly are provided. Example embodiments of the present invention can be found in the disclosure herein.

The method of the present invention disclosed herein is used for monitoring plug-in units in a rack, wherein a number of plug-in units and a power supply plug-in unit are provided in the rack, and a microcontroller, a power supply module and a monitoring assembly are arranged in each of the plug-in units, at least one of the plug-in units is effected by communication between a monitoring unit in the power supply plug-in unit and the monitoring assembly in the monitored plug-in unit.

According to an example embodiment of the present invention, the disclosed monitoring assembly is provided in a plug-in unit. If this plug-in unit is monitored, it is referred to herein as the monitored plug-in unit. The plug-in unit is arranged in a rack in which further plug-in units and a power supply plug-in unit are typically provided. This power supply plug-in unit is designed to monitor the plug-in units in the rack. For this purpose, communication is effected between the power supply plug-in unit and any plug-in units, which involves an exchange between the power supply plug-in unit and the respective monitoring assemblies in the plug-in units.

In current designs, each plug-in unit or enclosure (envelope) houses a high-level or highly integrated node (security domain) that is capable of detecting security-critical events and responding accordingly. With respect to hardware transition and permanent errors, the highly integrated node is to be able to monitor a fundamental hardware function, such as voltage, current, temperature, clock, etc.

In current designs, a specific plug-in unit, the power supply plug-in unit, is responsible for generating power and/or allocating power to other plug-in units, i.e. distributing the power provided. The advantage of this is that start-up and switch-off sequences are controlled by the start-up of a single node in order to achieve power equalization.

It has now been recognized that the main disadvantage is that there are also PMICs (power management ICs) within the plug-in units that generate power and/or distribute power locally. These PMICs also monitor local microcontrollers as external security agents. Thus, the status of the local power can only be passed on to the power supply plug-in unit after the microcontrollers have started up and are running and are communicating with other plug-in units via data buses or discrete signals, see FIG. 2.

The present invention improves and expands the voltage monitoring capability of the power supply plug-in unit to other plug-in units in the same rack. The present invention regularly uses monitoring assemblies with four-to-seven inputs in a so-called overturned design. The term “overturn” is used herein to emphasize that the voltages monitored by the components are those generated by the monitored plug-in unit after activation. However, instead of monitoring the microcontroller on the monitored plug-in unit, the monitoring assembly is monitored by the highly integrated node on the power supply plug-in unit. Thus, the request watchdog and secure response features are connected via an interface by enabling the power supply plug-in unit.

There are at least three types of application for this concept: type A, B and C. The concept can also be used based on similar devices, such as an automotive qualified 6-channel ASIL-D voltage monitor with an analog-to-digital converter (ADC) and a watchdog. In this connection, reference is made to FIG. 3.

Further advantages and embodiments of the present invention can be found in the disclosure herein and the figures.

Of course, the features mentioned above and those still to be explained below can be used not only in the respectively specified combinations but also in other combinations or alone, without departing from the scope of the present invention.

### BRIEF DESCRIPTION OF THE DRAWINGS

FIG. 1 shows a diagram of the steps involved in the transition from flat architectures to E/E zone architectures.

FIG. 2 shows a diagram of a typical integration of a highly integrated node.

FIG. 3 shows a block diagram of plug-in units connected via an interface within a rack architecture.

FIG. 4 shows a block diagram of an embodiment of the presented assembly for monitoring a voltage.

### DETAILED DESCRIPTION OF EXAMPLE EMBODIMENTS

The present invention is shown schematically in the figures on the basis of example embodiments and is described in detail below with reference to the figures.

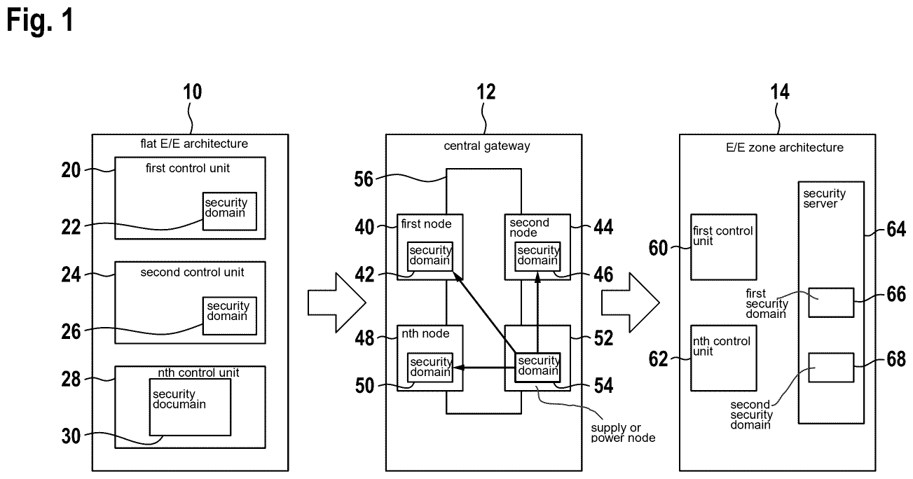

FIG. 1 shows a diagram of the steps involved in the transition from flat architectures to E/E zone architectures. The representation shows a flat E/E architecture 10 on the left, a central gateway 12 in the middle and an E/E zone architecture 14 on the right.

In the flat E/E architecture 10, a first control unit 20 with a security domain 22, a second control unit 24 with a security domain 26 and an nth control unit 28, which is designed as an nth security control unit 30, are provided.

A first node 40 with a security domain 42, a second node 44 with a security domain 46, an nth node 48 with a security domain 50 and a supply or power node 52 with a security domain 54 are provided in the central gateway 12. A trunk line 56 is also indicated.

A first control unit 60, an nth control unit 62 and a security server 64 are provided in the E/E zone architecture 14. In turn, a first security domain 66 and a second security domain 68 are provided in the security server 64.

The units 30, 54 and 68 are designed as monitoring units. The units 22, 26, 42, 46, 50 and 66 are designed as monitored units.

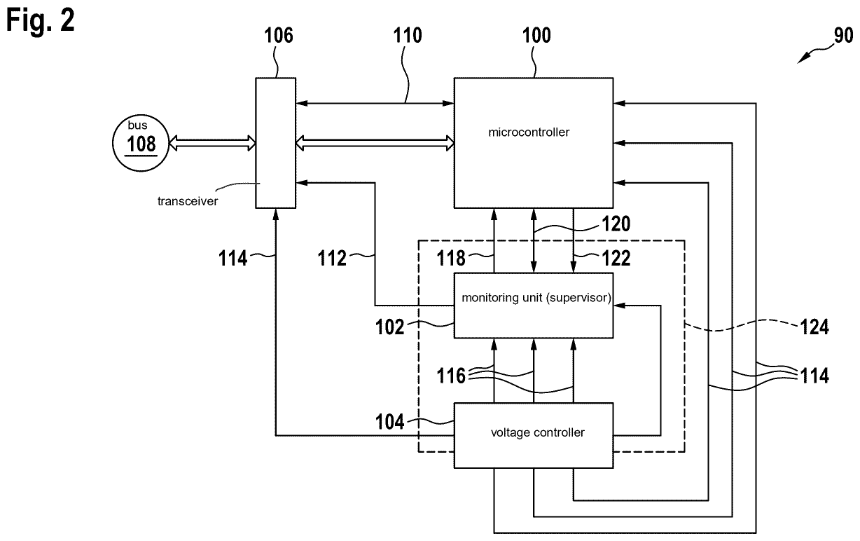

FIG. 2 shows a diagram of a typical plug-in unit 90 for a rack in the form of a highly integrated node. The representation shows a monitored microcontroller 100, a monitoring unit (supervisor) 102 along with a voltage controller 104. Furthermore, a transceiver 106 with a physical layer with a switch-off path is shown, which represents an interface to a bus 108.

Transmitted variables or signals are a control signal 110, an activation signal 112 for the switch-off path, a signal 114 for the generated or regulated voltage, a signal 116 for the monitored voltage, a reset signal 118, a query and response signal 120 for the watchdog interface and an error signal 122.

A power management circuit (PMIC: power management IC) 124 is also displayed. This is an integrated circuit with which the power of the entire system can be managed.

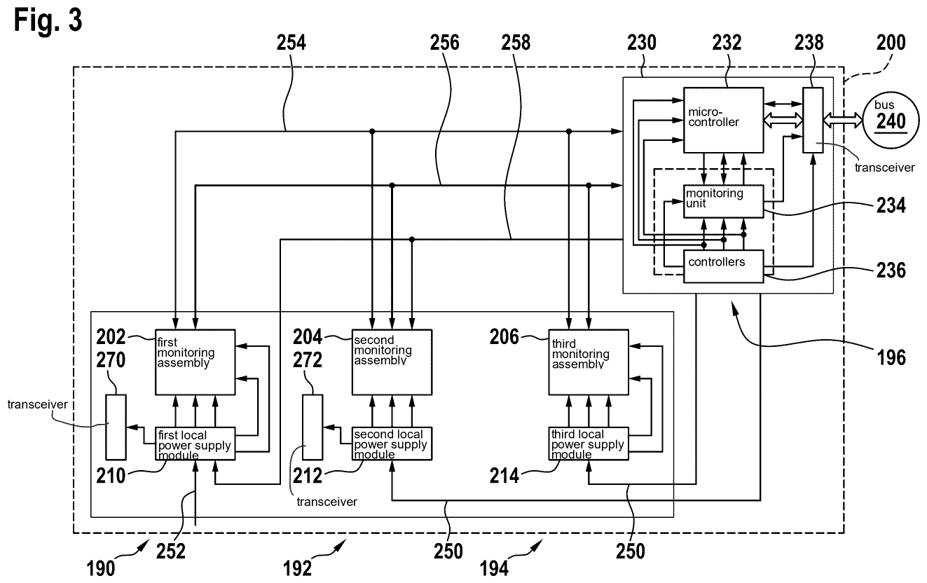

FIG. 3 shows a block diagram of plug-in units connecting via an interface within a rack architecture, wherein the rack as a whole is designated with the reference sign 200. The representation shows a first plug-in unit 190, a second plug-in unit 192 and a third plug-in unit 194. Furthermore, a plug-in unit 196 is provided, which is configured as a power supply plug-in unit 230 and is designed in accordance with the assembly 90 of FIG. 2 and is used to monitor the other plug-in units 190, 192, 194.

Furthermore, the representation shows in the plug-in units 190, 192, 194 a first monitoring assembly 202 of type A, a second monitoring assembly 204 of type B and a third monitoring assembly 206 of type C. A first local power supply module 210 is assigned to the first monitoring assembly 202, a second local power supply module 212 is assigned to the second monitoring assembly 204 and a third local power supply module 214 is assigned to the third monitoring assembly 206.

A monitored microcontroller 232, a monitoring unit 234 along with controllers 236 are provided in the power supply plug-in unit 230, which is implemented on the fourth plug-in unit 196. Furthermore, a transceiver 238 with a physical layer with a switch-off path is shown, which represents an interface to a bus 240.

Power supply inputs are designated with reference sign 250. A supply with external power is designated with reference sign 252. A line for a reset or interrupt is designated with reference sign 254. A line for a configuration and a query/response is designated with reference sign 256. A line for activation and deactivation is designated with reference sign 258. Reference signs 270 and 272 also designate transceivers.

Type A design: Externally supplied plug-in unit 190, enabled by the power supply plug-in unit

In FIG. 3, the type A plug-in unit 190 is permanently supplied by an external battery voltage (VINext). After the power supply plug-in unit 230 has started up and is running, the power supply module 210 or the power supply modules on the plug-in unit 190 provided are activated via an enable signal. The monitoring assembly 202 is supplied with voltage and enabled locally. The highly integrated node 232 on the power supply plug-in unit 230 is continued with a voltage monitoring configuration via I²C. Once configured, liveness testing or periodic testing can be initiated in order to make it possible for the highly integrated node on the power supply plug-in unit 230 to query the monitoring assembly 202.

If a UV/OV is detected by the monitoring assembly 202, an interrupt will be generated and the highly integrated node 232 on the power supply plug-in unit 230 will proceed with the secure response, for example by deactivating the power supply module 210 or the power supply modules on the provided plug-in unit 190.

Type B design: Controlledly supplied and enabled plug-in unit 192 by a power supply plug-in unit 230

In FIG. 3, the type B plug-in unit 192 is powered by a battery voltage rail (VIN) 250 controlled by the highly integrated node on the power supply plug-in unit 230 after the last one has started up and is running. The power supply module 212 or the power supply modules on the provided plug-in unit 192 is or are automatically activated after the voltage is applied. The monitoring assembly 204 is then supplied with voltage locally. Via an enable signal, the monitoring assembly 204 is enabled remotely by the highly integrated node 232 on the power supply plug-in unit 230. The highly integrated node on the power supply plug-in unit 230 will continue with a voltage monitoring configuration via I²C. Once configured, liveness testing or periodic testing can be initiated in order to make it possible for the highly integrated node on the power supply plug-in unit 230 to query the monitoring assembly 204.

If a UV/OV is detected by the monitoring assembly 204, an interrupt is generated and the highly integrated node on the power supply plug-in unit 230 will proceed with the secure response, for example it will interrupt the power supply from the provided plug-in unit 192.

Type C design: Controlledly supplied plug-in unit 194 by a power supply plug-in unit 230

In FIG. 3, the type C plug-in unit 194 is powered by a battery power rail (VIN) controlled by the highly integrated node on the power supply plug-in unit 230 after the last of these has started up and is running. The power supply module 214 or power supply modules on the provided plug-in unit 194 is or are automatically activated after the voltage is applied. The monitoring assembly 206 is then supplied with voltage locally and also enabled locally. The highly integrated node on the power supply plug-in unit 230 will continue with the voltage monitoring configuration via I²C. Once configured, liveness testing or periodic testing can be initiated in order allow for the highly integrated node on the power supply plug-in unit 230 to query the monitoring assembly 206.

If a UV/OV is detected by the monitoring assembly 206, an interrupt is generated and the highly integrated node on the power supply plug-in unit 230 will proceed with the secure response, for example it will disconnect the power supply from the provided plug-in unit 194.

The monitoring assembly 202, 204 or 206 provides a fully ASIL-compliant SoC power system monitor capable of meeting ASIL-D reliability if used with a controller 232 of the monitoring assembly 202, 204 or 206. This supports up to seven voltage monitoring inputs. Each input has programmable OV/UV threshold values (OV: overvoltage; UV: undervoltage). The controller 232 is assigned to the three monitoring assemblies 202, 204, 206.

The monitoring assembly 202, 204 or 206 contains a programmable flexible single sequence recorder (FPSR). This recorder stores power-on and power-off timestamps separately and supports on/off and idle/standby power sequences. It also comprises a programmable prompt/response watchdog that can be accessed via the I²C. interface, along with a configurable reset or RESET output.

The monitoring assembly 202, 204 or 206 increases reliability while significantly reducing system size and component count compared to separate integrated circuits (ICs) or discrete components.

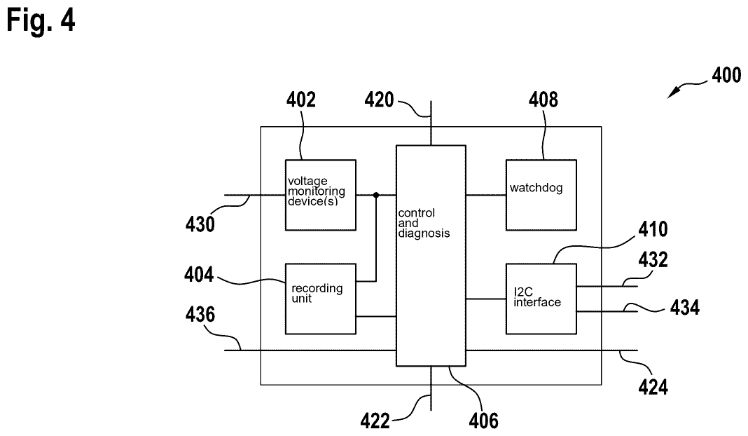

FIG. 4 shows a block diagram of an embodiment of the monitoring assembly, which is designated by the reference sign 400. The representation shows voltage monitoring devices 402, a recording unit 404 for a flexible power sequence, a unit 406 for control and diagnosis, a watchdog 408 with a window and an I²C interface 410.

The representation also shows a first terminal 420 for the supply voltage VDD and a second terminal 422 for ground. Furthermore, a third output 424 is provided for a reset signal.

The assembly 400 detects undervoltage and overvoltage states (reference sign 430) and triggers a fault response, for example via a reset (reference sign 424), if necessary. Furthermore, the assembly has programmable threshold values for both undervoltage and overvoltage and delays via the I²C interface 410 via signals SDA 432 (SD: serial data) and SCL 434 (SCL: serial clock). The recording unit 404 is used to store the switch-on and switch-off timestamps separately. Furthermore, the monitoring assembly supports 400 on/off and idle/standby power sequences (reference sign 436). Finally, the assembly 400 provides a challenge/response watchdog 408 with a window for external monitoring of a SoC (system on chip).

1-10. (canceled)

11. A method for monitoring plug-in units in a rack, wherein a number of plug-in units and a power supply plug-in unit are provided in the rack, and a microcontroller, a power supply module and a monitoring assembly are arranged in each of the plug-in units, the method comprising the following:
effecting at least one of the plug-in units by communication between a monitoring unit in the power supply plug-in unit, and the monitoring assembly in the monitored plug-in unit.

12. The method according to claim 11, wherein a voltage in the monitored plug-in unit is monitored.

13. The method according to claim 11, wherein the monitored plug-in unit is permanently supplied by an external power supply and the monitoring is effected by testing.

14. The method according to claim 11, wherein the monitored plug-in unit is supplied by a power source controlled by the power supply plug-in unit and the monitoring is effected by testing.

15. The method according to claim 11, wherein the monitored plug-in unit is powered by a battery voltage rail controlled by the power supply plug-in unit and the monitoring is effected by testing.

16. The method according to claim 13, wherein the monitoring is effected by periodic testing.

17. The method according to claim 13, wherein the monitoring is effected by liveness testing.

18. The method according to claim 13, wherein the communication between the power supply plug-in unit and the monitoring assembly of the monitored plug-in unit is effected via an I²C interface.

19. A monitoring assembly for monitoring a plug-in unit in a rack, a power supply plug-in unit being provided in the rack, the monitoring assembly being provided in a plug-in unit, the monitoring assembly being configured to:
effect the the plug-in units by communication between a monitoring unit in the power supply plug-in unit, and the monitoring assembly in the monitored plug-in unit.

20. The monitoring assembly according to claim 19, wherein the monitoring assembly is configured to monitor a voltage.
